(19) United States
(12) Patent Application Publication
(10) Pub. No.: US 2004/0124850 A1
(43) Pub. Date: Jul. 1, 2004

(54) Calibration circuit for current source and on-die terminations

(76) Inventor: Surya N. Koneru, Penang (MY)

Correspondence Address: John P. Ward, Blakely, Sokoloff, Taylor & Zafman LLP, Seventh Floor, 12400 Wilshire Boulevard, Los Angeles, CA, 90025-1030, US

(21) Appl. No.: 10/334,810

(22) Filed: Dec. 31, 2002

(51) Int. Cl. G01R 35/00

(52) U.S. Cl. 324/601

(57) ABSTRACT

A current calibration operation is performed within a calibration port. Following the current calibration operation, a termination resistor calibration operation is performed, also within the calibration port. A resistor calibration signal and a bias voltage signal are transmitted from the calibration port to a plurality of transmitter ports. A single external precision resistor is coupled to the calibration port for use during the current calibration operation.

### FIELD OF THE INVENTION

The present invention pertains to the field of semiconductor devices. More particularly, this invention pertains to the field of calibrating current sources and termination resistors.

### BACKGROUND OF THE INVENTION

In electronic systems, devices are often coupled to each other via interconnects. Each device on an interconnect may include transmitter ports to transmit information over the interconnect.

In current mode transmitters, it is highly desirable to keep the output voltage constant for reliable high-speed communication while also maintaining a constant termination resistance so that it is impedance matched with the interconnect media's impedance. In order to maintain constant output levels over constant termination values, a constant current source is needed.

In traditional current source implementations, an external precision resistor is used in each current source to keep the current constant. However, for designs with multiple transmitter ports, one external resistor per port would be expensive from a die-size point of view and also in pin count.

Further, in prior calibration schemes, only the resistor terminations are calibrated, and output levels were not calibrated. Because the output level of a current mode driver depends on both termination value and current source value, any change in current source value would cause variation in its output levels.

### BRIEF DESCRIPTION OF THE DRAWINGS

The invention will be understood more fully from the detailed description given below and from the accompanying drawings of embodiments of the invention which, however, should not be taken to limit the invention to the specific embodiments described, but are for explanation and understanding only.

FIG. 1 is a block diagram of a calibration port coupled to a number of transmitter ports.

FIG. 2 is a diagram of a calibration port.

FIG. 3 is a diagram of a transmitter port.

FIG. 4 is a flow diagram of a method for calibrating both current source and termination values.

### DETAILED DESCRIPTION

The dual-purpose calibration scheme disclosed herein utilizes a replica of the full size current mode transmitter to calibrate its current source and terminations. An example calibration port may include a reference bias generator, pre-drivers, on-die terminations and a current source. Maintaining a fixed voltage across a tune-able internal resistor generates a small current reference.

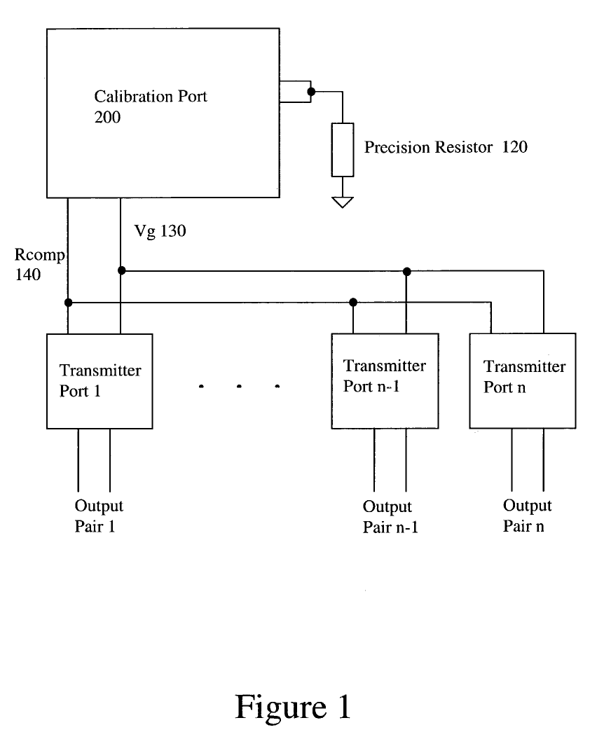

FIG. 1 is a block diagram of a calibration port 200 coupled to a number of transmitter ports 1 through n. The calibration port 200 is coupled to an external precision resistor 120. The calibration port 200 delivers a resistor compensation signal (Rcomp) 140 to the transmitter ports 1 through n. The calibration port 200 further delivers a bias voltage (Vg) 130 to the transmitter ports 1 through n. Each of the transmitter ports in this example output an output data pair (Output Pairs 1 through n).

The calibration port 200 and the transmitter ports in this example are located on one semiconductor die. The precision resistor 120 is located off of the die. The transmitter ports 1 through n may be coupled to an interconnect. The type of interconnect in this example would be a high-speed interconnect using differential signaling. As seen in FIG. 1, only one external precision resistor is used for a number of transmitter ports. The number of transmitter ports in this example may range from 2 to 16, although other implementations are possible using other numbers of transmitter ports.

Also, for this example embodiment, the precision resistor 120 has a value that is half that of the impedance of the interconnect coupled to the output pairs 1 through n.

The function of the calibration port 200 will be discussed in more detail below, but in general the calibration port 200 first performs a current calibration operation using the external precision resistor 120. The current calibration operation determines the bias voltage Vg 130. Following the current calibration operation, the calibration port 200 performs a termination resistance calibration operation. The termination resistance calibration operation determines an Rcomp 140 value. The Rcomp 140 and Vg values are communicated to the transmitter ports 1 through n. The Vg 130 value provides the transmitter ports 1 through n with a calibrated current source and the transmitter ports 1 through n use the Rcomp 140 value to adjust their termination resistors.

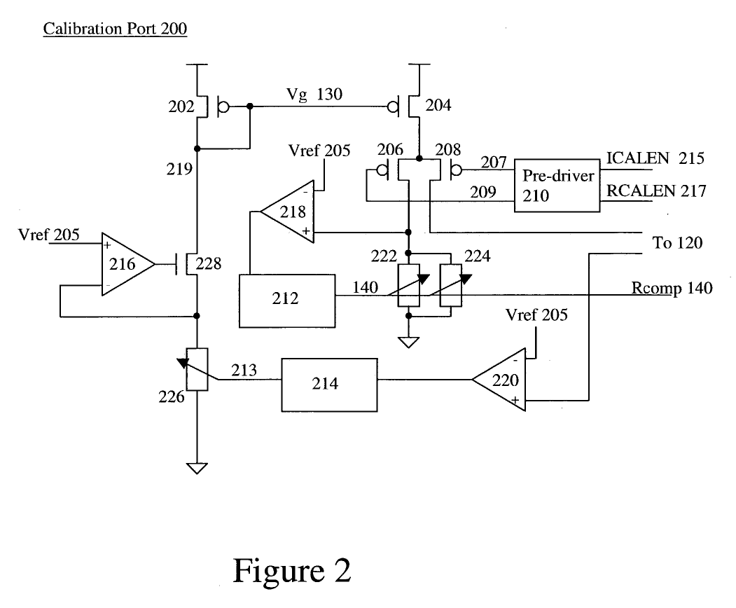

FIG. 2 is a diagram of the example calibration port 200. The current calibration operation is triggered by an assertion of the current calibration enable signal (ICALEN) 215. The ICALEN signal 215 is received at a pre-driver 210. The pre-driver 210, in response to the assertion of the ICALEN signal 215, enables a transistor 208 via signal 207. The transistor 208 allows a supply current supplied by a current source 204 to be delivered to the external precision resistor 120. A comparator 220 compares the voltage across the precision resistor 120 with a reference voltage (Vref) 205. The output of the comparator 220 is delivered to a state machine 214. The state machine 214 can cause the value of a variable resistor 226 to vary depending on the output of the comparator 220. The state machine 214 is coupled to the variable resistor 226 via signal 213. The state machine 214 will continue to vary the value of the variable resistor 226 until the voltage across the precision external resistor 120 matches the reference voltage Vref 205 value.

The comparator 216 and the transistor 228 form a source follower circuit. The source follower, in addition to a transistor 202 and the variable resistor 226, provide a reference current flowing through node 219. This reference current determines the value of the bias voltage Vg 130 supplied to the current source 204.

The current source 204 in one embodiment may include a number of transistors coupled in parallel in order to provide a full size current source.

Following the current calibration operation, a termination resistor calibration operation is started by an assertion of the RCALEN signal 217. In response to the assertion of the RCALEN signal 217, the pre-driver 210 causes the current source to be switched to drive variable termination resistors 222 and 224. The pre-driver 210 accomplishes this by turning on the transistor 206 via a signal 209 and by turning off the transistor 208.

A comparator 218 compares the voltage across the variable termination resistors 222 and 224 with the Vref 205 value. A state machine 212 will vary the resistance in the variable termination resistors 222 and 224 until the voltage across the resistors 222 and 224 matches the Vref 205 value. The value used to calibrate the termination resistors 222 and 224 is also output via the Rcomp signal 140.

The current calibration and termination resistor calibration operations may be repeated periodically in order to compensate for any voltage and temperature drift.

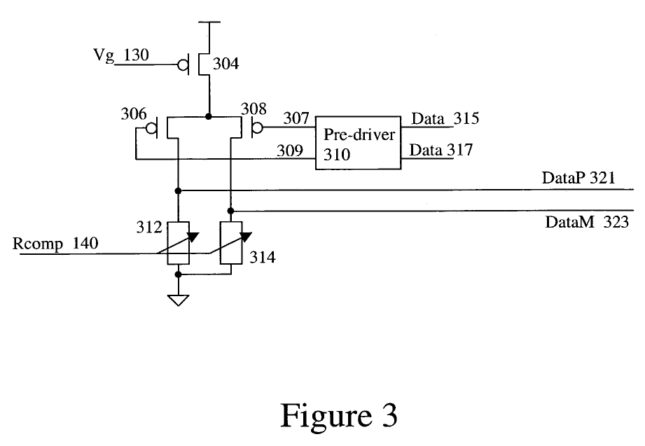

FIG. 3 is a diagram of an example transmitter port. The bias voltage Vg 130 generated at the calibration port 200 is applied to a current source 304. The current source 304 may be a number of transistors coupled in parallel. The Rcomp signal 140 is used to adjust a pair of variable termination resistors 312 and 314. Data is received at the transmitter port over the internal data signal pair 315 and 317. The pre-driver 310 directs the source current to either the datap output line 321 or the datam output line 323 depending one the values received over the lines 315 and 317. The pre-driver 310 directs the source current via the transistors 306 and 308. The pre-driver 310 is coupled to the transistors 306 and 308 by way of the signals 309 and 307, respectively.

As seen above, the bias voltage generator is common to the calibration port and to the transmitter ports. So, once the bias current is tuned to the target value, this same current is replicated in all of the transmitter ports by mirroring the bias voltage exactly as the calibration port does. By utilizing the full size current source in calibration, any of the process mismatch induced errors between current source and current reference are reduced. By maintaining a constant voltage across the internal reference resistor, current bias transistors are maintained in saturation region and thus improve power supply rejection.

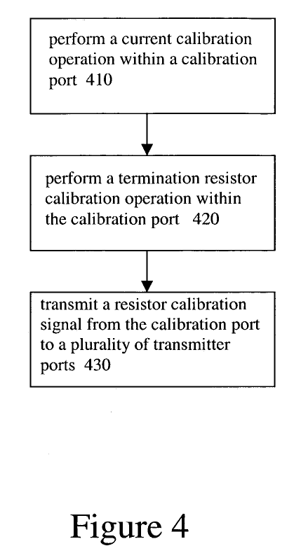

FIG. 4 is a flow diagram of a method for calibrating both current source and termination values. At block 410, a current calibration operation is performed. The current calibration operation is performed within a calibration port. Following the current calibration operation, a termination resistor calibration operation is performed at block 420. The termination resistor calibration operation is also performed with the calibration port. After the termination resistor calibration operation, a resistor calibration signal is transmitted from the calibration port to a plurality of transmitter ports.

In the foregoing specification the invention has been described with reference to specific exemplary embodiments thereof. It will, however, be evident that various modifications and changes may be made thereto without departing from the broader spirit and scope of the invention as set forth in the appended claims. The specification and drawings are, accordingly, to be regarded in an illustrative rather than in a restrictive sense.

Reference in the specification to “an embodiment,” “one embodiment,” “some embodiments,” or “other embodiments” means that a particular feature, structure, or characteristic described in connection with the embodiments is included in at least some embodiments, but not necessarily all embodiments, of the invention. The various appearances of “an embodiment,” “one embodiment,” or “some embodiments” are not necessarily all referring to the same embodiments.

What is claimed is:

1. An apparatus, comprising:
a calibration port coupled to an external precision resistor; and
a plurality of transmitter ports coupled to the calibration port via a resistor compensation signal and a bias voltage signal.

2. The apparatus of claim 1, wherein the calibration port is coupled to a first terminal of the external precision resistor and wherein a second terminal of the external precision resistor is coupled to a ground source.

3. The apparatus of claim 2, wherein the external precision resistor has a value equal to that of one half of a termination resistance value.

4. The apparatus of claim 3, the calibration port to perform a current calibration operation.

5. The apparatus of claim 4, the calibration port to perform a termination resistance calibration operation following the current calibration operation.

6. The apparatus of claim 5, the calibration port to output the resistor compensation signal following the termination resistance calibration operation.

7. The apparatus of claim 6, the plurality of transmission ports each including at least one variable termination resistor, the at least one variable termination resistors varying in value according to the resistor compensation signal.

8. The apparatus of claim 7, the calibration port including a pre-driver circuit to enable a first transistor in response to detecting an assertion of a current calibration enable signal, the first transistor to pass a current from a first current source to the first terminal of the external resistor.

9. The apparatus of claim 8, the calibration port further including a first comparator to compare the voltage at the first terminal of the external precision resistor with a reference voltage, the comparator to output the results of the comparison to a first state machine, the first state machine to cause a variable current compensation resistor to vary in value according to a current compensation signal output by the first state machine.

10. The apparatus of claim 9, the current compensation resistor including a first terminal and a second terminal, the second terminal coupled to a ground source, the first terminal coupled to a reference current source.

11. The apparatus of claim 10, the first current source to vary its output according to a bias voltage, the bias voltage varying according to variations in the current compensation resistor.

12. The apparatus of claim 11, the calibration port including a pre-driver circuit to enable a second transistor in response to detecting an assertion of a resistor calibration enable signal, the second transistor to pass the current from the first current source to a first and a second variable termination resistor, the first and second variable termination resistors each including a first and a second terminal, the current from the first current source applied to the first terminals of the first and second variable termination resistors, the second terminals of the first and second variable termination resistors coupled to a ground source.

13. The apparatus of claim 12, including a second comparator to compare the voltage at the first terminals of the first and second variable termination resistors with the reference voltage, the comparator to output the results of the comparison to a second state machine, the state machine to output the resistor compensation signal to the first and second variable termination and also to the plurality of transmitter ports.

14. A method, comprising:
performing a current calibration operation within a calibration port;
performing a termination resistor calibration operation within the calibration port following the current calibration operation; and
transmitting a resistor calibration signal from the calibration port to a plurality of transmitter ports.

15. The method of claim 14, further comprising each of the plurality of transmitter ports adjusting at least one variable termination resistor according to the resistor calibration signal.

16. A system, comprising:
a first device; and
a second device coupled to the first device via an interconnect, the second device including
a calibration port coupled to an external precision resistor, and
a plurality of transmitter ports coupled to the calibration port via a resistor compensation signal and a bias voltage signal, the plurality of transmitter ports to couple the second device to the interconnect.

17. The system of claim 16, wherein the calibration port is coupled to a first terminal of the external precision resistor and wherein a second terminal of the external precision resistor is coupled to a ground source.

18. The system of claim 17, wherein the external precision resistor has a value equal to that of one half of a termination resistance value.

19. The system of claim 18, the calibration port to perform a current calibration operation.

20. The system of claim 19, the calibration port to perform a termination resistance calibration operation following the current calibration operation.

21. The system of claim 20, the calibration port to output the resistor compensation signal following the termination resistance calibration operation.

22. The system of claim 21, the plurality of transmission ports each including at least one variable termination resistor, the at least one variable termination resistors varying in value according to the resistor compensation signal.
